(19) United States
(12) Patent Application Publication
(10) Pub. No.: US 2021/0028167 A1
(43) Pub. Date: Jan. 28, 2021

(54) ANALOG INTEGRATED CIRCUIT WITH IMPROVED TRANSISTOR LIFETIME AND METHOD FOR MANUFACTURING THE SAME

(71) Applicants: ZHENG ZUO, LOS ANGELES, CA (US); NA REN, LOS ANGELES, CA (US); RUIGANG LI, LOS ANGELES, CA (US)

(72) Inventors: ZHENG ZUO, LOS ANGELES, CA (US); NA REN, LOS ANGELES, CA (US); RUIGANG LI, LOS ANGELES, CA (US)

(73) Assignee: AZ Power, Inc, CULVER CITY, CA (US)

(21) Appl. No.: 16/870,950

(22) Filed: May 9, 2020

Related U.S. Application Data
(60) Provisional application No. 62/877,169, filed on Jul. 22, 2019.

(51) Int. Cl. H01L 27/088; H01L 21/02; H01L 21/761; H01L 29/49; H01L 29/08; H01L 23/31; H01L 23/29; H01L 21/8234; H01L 21/28; H01L 21/311; H01L 29/51

(52) U.S. Cl. CPC H01L 27/088; H01L 21/02255; H01L 21/0214; H01L 21/761; H01L 29/4916; H01L 29/0847; H01L 23/3171; H01L 23/291; H01L 21/823481; H01L 21/823418; H01L 21/823437; H01L 21/28035; H01L 21/02233; H01L 21/31116; H01L 29/518; H01L 21/02164

(57) ABSTRACT

In one aspect, a method for manufacturing an analog integrated circuit with improved transistor lifetime includes steps of: providing a P-type substrate; forming N+ source/drain regions; forming a P⁺ isolation island to separate a high voltage I/O transistor and low voltage core transistor; patterning a SiON dielectric layer on one side of the P⁺ isolation island for the high voltage I/O transistor; patterning a SiO₂ dielectric layer on the other side of the P⁺ isolation island for the low voltage core transistor; forming a gate structure for the low voltage core transistor and high voltage I/O transistor; forming a gate polysilicon layer on a top portion of each of the SiO₂ and SiON dielectric layers; forming a SiON passivation layer with open holes; and forming a source electrode, a gate electrode and a drain electrode for each of the low voltage core transistor and high voltage I/O transistor.

### CROSS-REFERENCE TO RELATED APPLICATIONS

This application claims priority under 35 U.S.C. § 119(e) to U.S. Provisional Patent Application Ser. No. 62/877,169, filed on Jul. 22, 2019, the entire contents of which are hereby incorporated by reference.

### FIELD OF THE INVENTION

The present invention relates to analog integrated circuits, particularly, relates to analog integrated circuits with improved transistor lifetime.

### BACKGROUND OF THE INVENTION

In the process of analog integrated circuits, due to high requirement of device noise robustness performance, silicon dioxide dielectric is preferable for the gate oxide layer. This is different from digital integrated circuits process, in which SiON dielectric is used for the gate oxide layer. Therefore, the lifetime performance for the transistor in analog integrated circuits is limited.

The Si—H dangling bond in SiO₂ gate oxide layer has a lower activation energy than Si—N dangling bond in SiON gate oxide layer. Therefore, in metal-oxide-semiconductor field effect transistors, if SiON dielectric layer is used as the gate oxide layer, the device lifetime can be improved by two orders of magnitude. For example, in 0.18 μm process, the input and output transistors have a standard lifetime of 40 years while SiO₂ dielectric layer only have 0.1-0.3 year. The international quality standard for room temperature condition is 0.2 year. If considering 1/50 as life cycle, the transistor could have 50 times, that is 10 years lifetime. So, transistors using SiON dielectric as gate oxide layer can have 4 times higher lifetime than using SiO₂. However, transistors using SiON dielectric as gate oxide layer may have much higher 1/f noise.

For example, in 0.18 μm criteria dimension based analog integrated circuits, basically there are two kinds of device: 1.8V core NFET/PFET devices and 3.3V input/output devices. For 1.8V devices, the low voltage of 1.8V establish an electric field on 1.12 eV band-gap semiconductor. In this condition, the hot electron emission has no damage effect in channel region. For 3.3V input/output devices, the high voltage of 3.3V establishes a high electric field and leads to a high damage to the device's lifetime by the hot electron emission.

Therefore, there remains a need for a new and improved analog integrated circuit to address the tradeoff between lifetime and noise robustness design requirement for the transistor in analog integrated circuits, using the SiON dielectric layer as a gate oxide layer for the high voltage I/O transistor while the SiO₂ dielectric layer as a gate oxide layer for the low voltage core transistor.

### SUMMARY OF THE INVENTION

It is an object of the present invention to provide an analog integrated circuit with a balance of improved transistor lifetime and noise robustness.

It is another object of the present invention to provide an analog integrated circuit with improved transistor lifetime, wherein the SiON dielectric layer as a gate oxide layer for the high voltage I/O transistor while the SiO₂ dielectric layer as a gate oxide layer for the low voltage core transistor.

In one aspect, an analog integrated circuit with improved transistor lifetime may include a substrate, an N⁺ drain/source region, an isolation island, a SiON dielectric gate oxide layer for a high voltage I/O transistor, an SiO₂ dielectric gate oxide layer for a low voltage core transistor, a gate polysilicon, an SiON passivation layer, a source electrode for the low voltage core transistor, a gate electrode for the low voltage core transistor, a drain electrode for the low voltage core transistor, a drain electrode for the high voltage I/O transistor, a gate electrode for the high voltage I/O transistor, and a source electrode for the high voltage I/O transistor.

In one embodiment, the substrate is either a P well or a P-type substrate, and the N⁺ drain/source region is a heavily doped N-type region, and connected with the drain/source electrode on each side. The isolation island is a heavily doped P-type region to isolate the low voltage core transistor device from the high voltage I/O transistor device.

It is important to note that the gate oxide for a high voltage I/O transistor device is a SiON dielectric layer, which is used to improve the lifetime of the I/O transistor device in analog integrated circuit. On the other hand, the gate oxide for the low voltage core transistor device is SiO₂ dielectric layer, which is just the same as traditional method to remain high noise resistance of analog integrated circuits.

In a further embodiment, the gate polysilicon is located on the top portion of the gate oxide layer for the gate signal conduction, and the SiON passivation layer is located on top of the transistor to protect it from an outer environment. It is noted that the source electrode is a metal filled into the hole of SiON passivation, which is located on top of the N⁺ source region in the low voltage core transistor; the gate electrode is a metal filled into the hole of SiON passivation, which is located on top of the gate polysilicon in the low voltage core transistor; and the drain electrode is a metal filled into the hole of SiON passivation, which is located on top of the N⁺ drain region in low voltage core transistor.

Likewise, on the high voltage I/O transistor side, the drain electrode is a metal filled into the hole of SiON passivation, which is located on top of the N⁺ drain region in the high voltage I/O transistor; the gate electrode is a metal filled into the hole of SiON passivation, which is located on top of the gate polysilicon in the high voltage I/O transistor; and the source electrode is a metal filled into the hole of SiON passivation, which is located on top of the N⁺ drain region in the high voltage I/O transistor.

In another aspect, a method for manufacturing an analog integrated circuit with improved transistor lifetime may include steps of: providing a P-type substrate; forming a plurality of N⁺ source/drain regions at the top portion of the substrate; forming a P⁺ island to separate a high voltage I/O transistor and a low voltage core transistor; depositing and patterning a SiON dielectric layer on one side of the P⁺ isolation island for the high voltage I/O transistor; depositing and patterning a SiO₂ dielectric layer on the other side of the P⁺ isolation island for the low voltage core transistor; forming a gate structure for the low voltage core transistor and the high voltage I/O transistor by patterning the SiO₂ and SiON dielectric layers; forming a gate polysilicon layer on a top portion of each of the SiO₂ and SiON dielectric layers; forming a SiON passivation layer with a plurality of open holes on top of both the high voltage I/O transistor and low voltage core transistor; forming a source electrode, a gate electrode and a drain electrode for the low voltage core transistor; and forming a source electrode, a gate electrode and a drain electrode for the high voltage I/O transistor.

In one embodiment, the step of providing a P-type substrate may include the step of diffusing or implanting P-type dopants, such as boron or aluminum ions to create a P-type substrate or P-type well. The step of forming a plurality of N+ source/drain regions may include the step of diffusing or implanting N-type dopants, such as nitrogen or phosphorus ions to create N⁺ regions in the substrate for both the low voltage core transistor and high voltage I/O transistor.

In another embodiment, the step of forming a P⁺ isolation island may include the step of diffusing or implanting P-type dopants, such as boron or aluminum ions to create the P⁺ isolation island, which is used to separate the low voltage core transistor from the high voltage I/O transistor.

In still another embodiment, the step of depositing and patterning a SiON dielectric layer on a high voltage I/O transistor may include steps of conducting thermal oxidation or deposition of SiON dielectric layer on top of the substrate, and etching away the SiON dielectric layer on the low voltage core transistor side. In a further embodiment, the etching techniques may include dry etching techniques.

Likewise, the step of depositing and patterning a SiO₂ dielectric layer on a low voltage core transistor may include steps of conducting thermal oxidation or deposition of SiO₂ dielectric layer top of the substrate, and etching away the SiO₂ dielectric layer on the high voltage I/O transistor side. In a further embodiment, the etching techniques may include dry etching techniques.

In a still a further embodiment, the step of forming a source electrode, a gate electrode and a drain electrode for the low voltage core transistor may include the step of filling metal into the open holes of the SiON passivation layer on top of the source, the gate and the drain regions of the low voltage core transistor.

Likewise, the step of forming a source electrode, a gate electrode and a drain electrode for the high voltage I/O transistor may include the step of filling metal into the open holes of the SiON passivation layer on top of the source, the gate and the drain regions of the high voltage I/O transistor.

It is important to note that in the invention, the SiON dielectric layer is used to form the gate oxide layer for the high voltage I/O transistor. Instead of traditional SiO₂ based gate oxide layer for both high voltage I/O transistor and low voltage core transistor, the SiON dielectric layer is used in the present invention to improve the lifetime of the high voltage I/O transistor for the analog integrated circuit. On the other hand, the high noise-resistant performance for the low voltage core transistor can be remained because of the SiO₂ dielectric layer on the low voltage side.

The present invention is advantageous because the analog integrated circuit has different gate oxide layers for the high voltage I/O transistor device and low voltage core transistor device. More specifically, the gate oxide layer for the high voltage I/O transistor device uses the SiON dielectric layer to improve the lifetime, while the SiO₂ dielectric layer is used for the low voltage core transistor device for the noise resistance. Since the Si—N dangling bond in SiON gate oxide layer has a higher activation energy than Si—H dangling bond in SiO₂ gate oxide layer, in metal-oxide-semiconductor field effect transistors, the use of SiON dielectric layer as the gate oxide layer can improve the device lifetime by two orders of magnitude.

### BRIEF DESCRIPTION OF THE DRAWINGS

FIG. 1 is a cross-section view of the analog integrated circuit with improved transistor lifetime in the present invention.

FIGS. 2A-2E illustrate cross-section views of a method for manufacturing an analog integrated circuit with improved transistor lifetime in the present invention.

FIG. 3 illustrates a flow diagram of a method for manufacturing an analog integrated circuit with improved transistor lifetime in the present invention.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

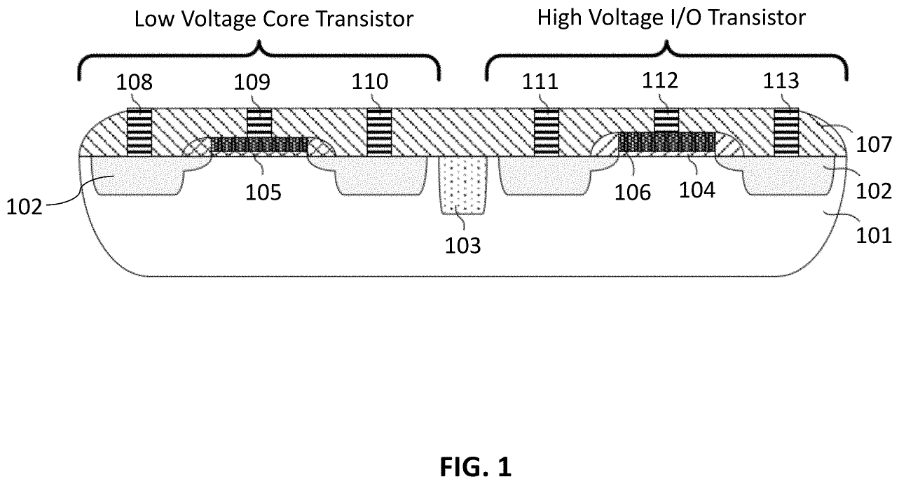

In one aspect, as shown in FIG. 1, an analog integrated circuit with improved transistor lifetime may include a substrate 101, an N⁺ drain/source region 102, a P⁺ isolation island 103, a SiON dielectric gate oxide layer 104 for a high voltage I/O transistor, an SiO₂ dielectric gate oxide layer 105 for a low voltage core transistor, a gate polysilicon 106, an SiON passivation layer 107, a source electrode 108 for the low voltage core transistor, a gate electrode 109 for the low voltage core transistor, a drain electrode 110 for the low voltage core transistor, a drain electrode 111 for the high voltage I/O transistor, a gate electrode 112 for the high voltage I/O transistor, and a source electrode 113 for the high voltage I/O transistor.

In one embodiment, the substrate 101 is either a P well or a P-type substrate, and the N⁺ drain/source region 102 is a heavily doped N-type region, and connected with the drain/source electrode on each side. The P⁺ isolation island 103 is a heavily doped P-type region to isolate the low voltage core transistor device from the high voltage I/O transistor device.

It is important to note that the gate oxide 104 for a high voltage I/O transistor device is a SiON dielectric layer, which is used to improve the lifetime of the I/O transistor device in analog integrated circuit. On the other hand, the gate oxide 105 for the low voltage core transistor device is SiO₂ dielectric layer, which is just the same as traditional method to remain the high noise robustness of analog integrated circuits.

In a further embodiment, the gate polysilicon 106 is located on a top portion of the gate oxide layer for the gate signal conduction, and the SiON passivation layer 107 is located on top of the transistor to protect it from an outer environment. It is noted that the source electrode 108 is a metal filled into the hole of SiON passivation 107, which is located on top of the N⁺ source region in the low voltage core transistor; the gate electrode 109 is a metal filled into the hole of SiON passivation 107, which is located on top of the gate polysilicon 106 in the low voltage core transistor; and the drain electrode 110 is a metal filled into the hole of SiON passivation 107, which is located on top of the N⁺ drain region in low voltage core transistor.

Likewise, on the high voltage I/O transistor side, the drain electrode 111 is a metal filled into the hole of SiON passivation 107, which is located on top of the N⁺ drain region in the high voltage I/O transistor; the gate electrode 112 is a metal filled into the hole of SiON passivation 107, which is located on top of the gate polysilicon in the high voltage I/O transistor; and the source electrode 113 is a metal filled into the hole of SiON passivation 107, which is located on top of the N⁺ drain region in the high voltage I/O transistor.

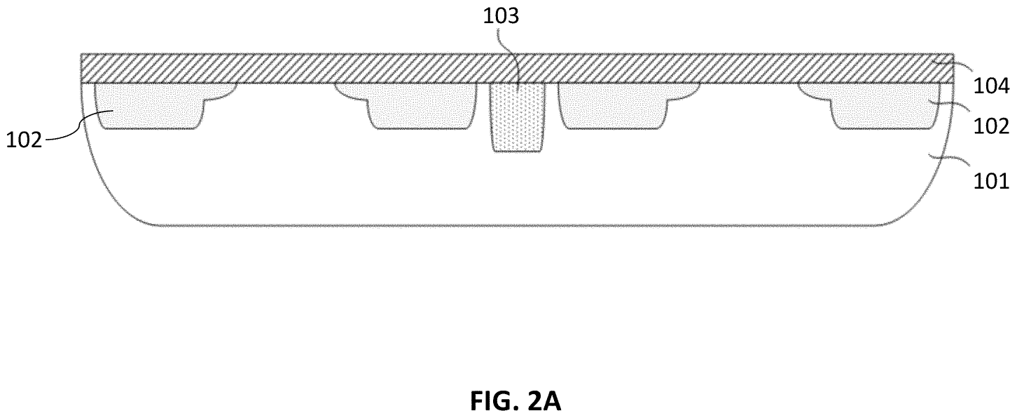

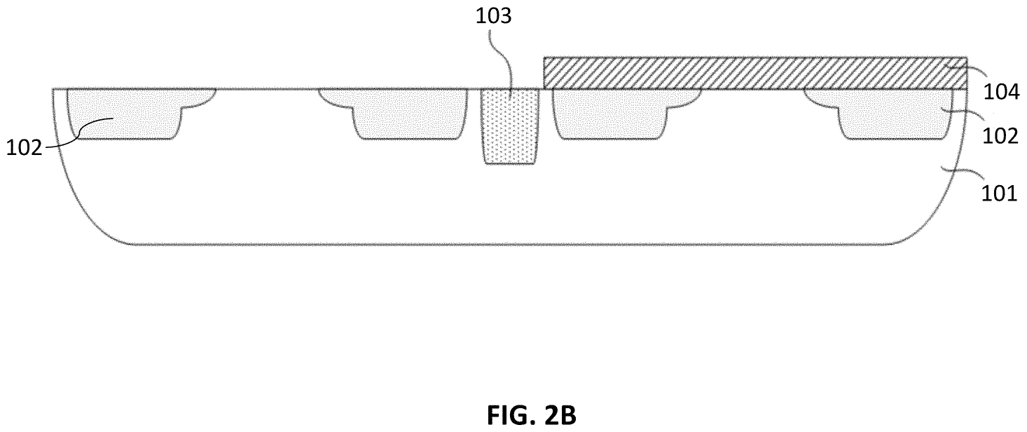

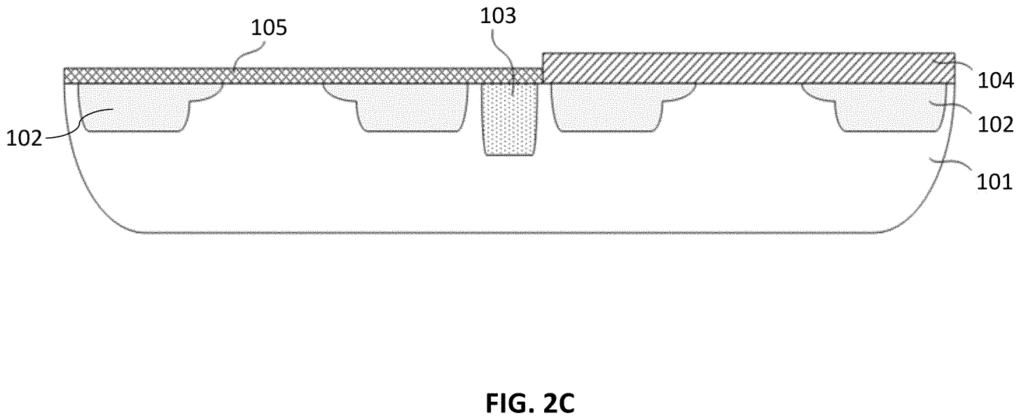

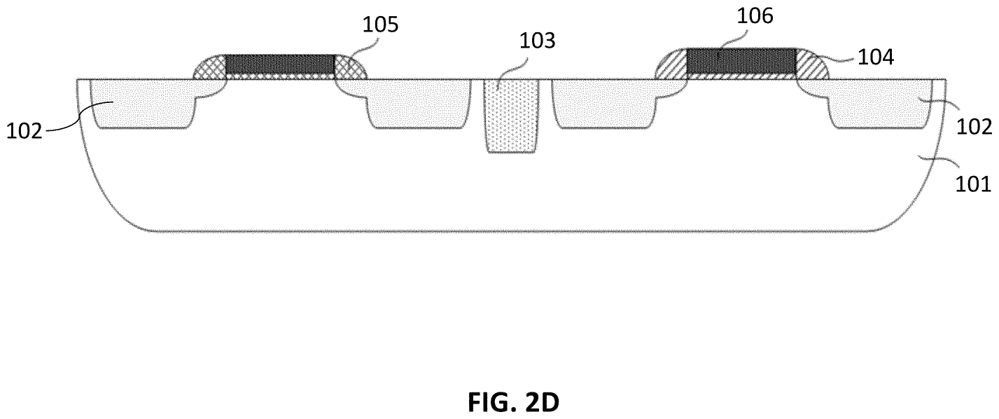

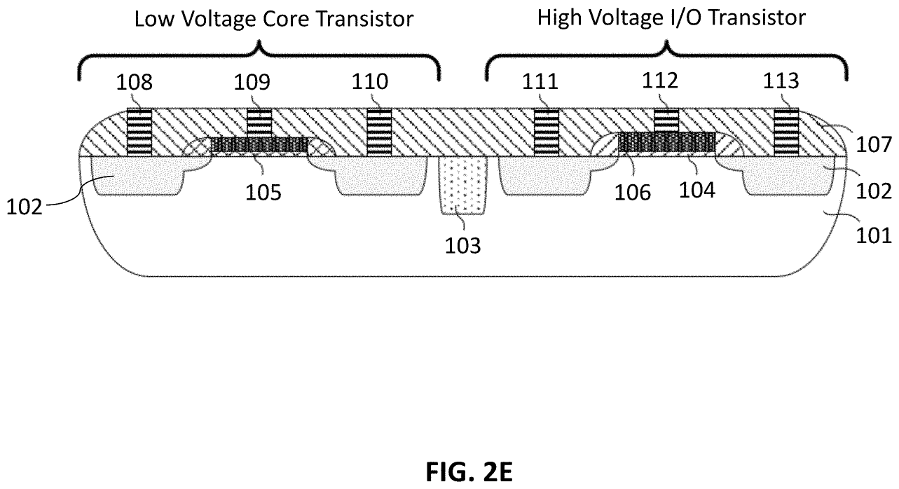

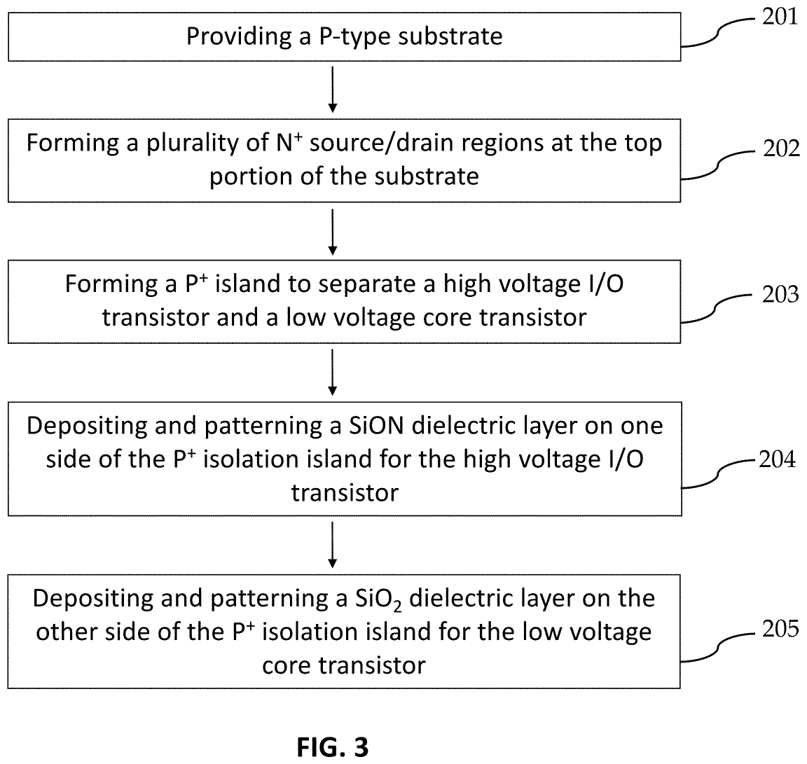

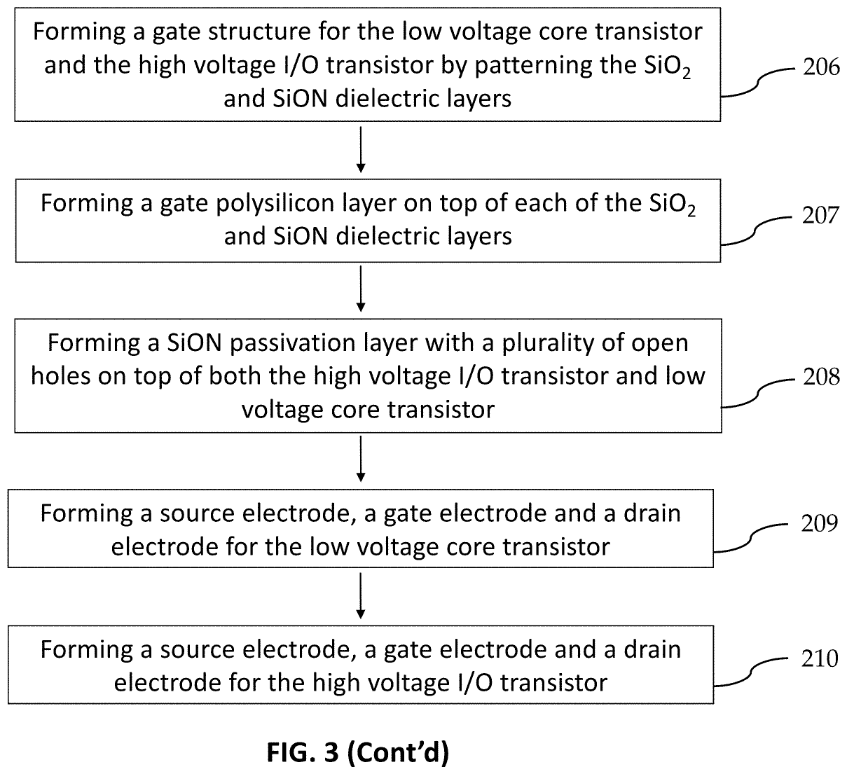

In another aspect, as shown in FIGS. 2A to 2E, a method for manufacturing an analog integrated circuit with improved transistor lifetime may include steps of: providing a P-type substrate (201); forming a plurality of N⁺ source/drain regions at the top portion of the substrate (202); forming a P⁺ island to separate a high voltage I/O transistor and a low voltage core transistor (203); depositing and patterning a SiON dielectric layer on one side of the P⁺ isolation island for the high voltage I/O transistor (204); depositing and patterning a SiO₂ dielectric layer on the other side of the P⁺ isolation island for the low voltage core transistor (205); forming a gate structure for the low voltage core transistor and the high voltage I/O transistor by patterning the SiO₂ and SiON dielectric layers (206); forming a gate polysilicon layer on a top portion of each of the SiO₂ and SiON dielectric layers (207); forming a SiON passivation layer with a plurality of open holes on top of both the high voltage I/O transistor and low voltage core transistor (208); forming a source electrode, a gate electrode and a drain electrode for the low voltage core transistor (209); and forming a source electrode, a gate electrode and a drain electrode for the high voltage I/O transistor (210).

In one embodiment, the step of providing a P-type substrate (201) may include the step of diffusing or implanting P-type dopants, such as boron or aluminum ions to create a P well or a P-type substrate. The step of forming a plurality of N⁺ source/drain regions (202) may include the step of diffusing or implanting N-type dopants, such as nitrogen or phosphorus ions to create N⁺ regions in the substrate for both the low voltage core transistor and high voltage I/O transistor.

In another embodiment, the step of forming a P⁺ isolation island (203) may include the step of diffusing or implanting P-type dopants, such as boron or aluminum ions to create the P⁺ isolation island, which is used to separate the low voltage core transistor from the high voltage I/O transistor.

In still another embodiment, the step of depositing and patterning a SiON dielectric layer on a high voltage I/O transistor (204) may include steps of conducting thermal oxidation or deposition of SiON dielectric layer on top of the substrate, and etching away the SiON dielectric layer on the low voltage core transistor side. In a further embodiment, the etching techniques may include dry etching techniques.

Likewise, the step of depositing and patterning a SiO₂ dielectric layer on a low voltage core transistor (205) may include steps of conducting thermal oxidation or deposition of SiO₂ dielectric layer on top of the substrate, and etching away the SiO₂ dielectric layer on the high voltage I/O transistor side. In a further embodiment, the etching techniques may include dry etching techniques.

In a still a further embodiment, the step of forming a source electrode, a gate electrode and a drain electrode for the low voltage core transistor (209) may include the step of filling metal into the open holes of the SiON passivation layer on top of the source, the gate and the drain regions of the low voltage core transistor.

Likewise, the step of forming a source electrode, a gate electrode and a drain electrode for the high voltage I/O transistor (210) may include the step of filling metal into the open holes of the SiON passivation layer on top of the source, the gate and the drain regions of the high voltage I/O transistor.

It is important to note that in the invention, the SiON dielectric layer is used to form the gate oxide layer for the high voltage I/O transistor 104. Instead of traditional SiO₂ based gate oxide layer for both high voltage I/O transistor and low voltage core transistor, the SiON dielectric layer is used in the present invention to improve the lifetime of the high voltage I/O transistor for the analog integrated circuit. On the other hand, the high noise-resistant performance for the low voltage core transistor can be remained because of the SiO₂ dielectric layer on the low voltage side.

The present invention is advantageous because the analog integrated circuit has different gate oxide layers for the high voltage I/O transistor device and low voltage core transistor device. More specifically, the gate oxide layer 104 for the high voltage I/O transistor device uses the SiON dielectric layer to improve the lifetime, while the SiO₂ dielectric layer 105 is used for the low voltage core transistor device for the noise resistance. Since the Si—N dangling bond in SiON gate oxide layer 104 has a higher activation energy than Si—H dangling bond in SiO₂ gate oxide layer 105, in metal-oxide-semiconductor field effect transistors, the use of SiON dielectric layer as the gate oxide layer can improve the device lifetime by two orders of magnitude.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. An analog integrated circuit with improved transistor lifetime comprising:
a substrate of a first conductivity type;
a plurality of source/drain regions of a second conductivity type;
a first gate oxide of a high voltage (input/output) I/O transistor;
a second gate oxide of a low voltage core transistor;
an isolation island of the first conductivity type to separate the high voltage I/O transistor and low voltage core transistor;
a gate polysilicon formed on a top portion of each of the first gate oxide and second gate oxide;
a SiON passivation layer; and
a drain electrode, source electrode and gate electrode for each of the low voltage core transistor and high voltage I/O transistor,
wherein the first gate oxide is a SiON dielectric layer, which is used to improve the lifetime of the I/O transistor device in the analog integrated circuit; and the second gate oxide is a SiO₂ dielectric layer, which is used to remain high noise robustness in the analog integrated circuits.

2. The analog integrated circuit with improved transistor lifetime of claim 1, wherein the substrate is a P-type substrate.

3. The analog integrated circuit with improved transistor lifetime of claim 1, wherein the source/drain regions are N⁺ source/drain regions.

4. The analog integrated circuit with improved transistor lifetime of claim 1, wherein the isolation island is a heavily doped P-type region to separate the low voltage core transistor device from the high voltage I/O transistor device.

5. The analog integrated circuit with improved transistor lifetime of claim 1, wherein the SiON passivation layer has a plurality of open holes on top of the drain/source regions and the gate polysilicon for both the high voltage I/O transistor and low voltage core transistor.

6. The analog integrated circuit with improved transistor lifetime of claim 5, wherein the drain/source electrodes and gate electrode are formed when metal is filled into the open holes on top of the drain/source regions and the gate polysilicon for both the high voltage I/O transistor and low voltage core transistor.

7. A manufacturing method for an analog integrated circuit with improved transistor lifetime comprising steps of:
providing a substrate of a first conductivity type;
forming a plurality of source/drain regions of a second conductivity type at the top portion of the substrate;
forming an isolation island to separate a high voltage (input/output) I/O transistor and a low voltage core transistor;
depositing and patterning a SiON dielectric layer on one side of the P⁺ isolation island for the high voltage I/O transistor;
depositing and patterning a SiO₂ dielectric layer on the other side of the P⁺ isolation island for the low voltage core transistor;
forming a gate structure for the low voltage core transistor and the high voltage I/O transistor by patterning the SiO₂ and SiON dielectric layers;
forming a gate polysilicon layer on a top portion of each of the SiO₂ and SiON dielectric layers;
forming a SiON passivation layer with a plurality of open holes on top of both the high voltage I/O transistor and low voltage core transistor;
forming a source electrode, a gate electrode and a drain electrode for the low voltage core transistor; and
forming a source electrode, a gate electrode and a drain electrode for the high voltage I/O transistor.

8. The manufacturing method for an analog integrated circuit with improved transistor lifetime of claim 7, wherein the step of providing a substrate of a first conductivity includes the step of diffusing or implanting P-type dopants, such as boron or aluminum ions to create a P well or a P-type substrate.

9. The manufacturing method for an analog integrated circuit with improved transistor lifetime of claim 7, wherein the step of forming a plurality of source/drain regions of a second conductivity type includes the step of diffusing or implanting N-type dopants, such as nitrogen or phosphorus ions to create N⁺ regions in the substrate for both the low voltage core transistor and high voltage I/O transistor.

10. The manufacturing method for an analog integrated circuit with improved transistor lifetime of claim 7, wherein the step of forming an isolation island includes the step of diffusing or implanting P-type dopants, such as boron or aluminum ions to create the P⁺ isolation island.

11. The manufacturing method for an analog integrated circuit with improved transistor lifetime of claim 7, wherein the step of depositing and patterning a SiON dielectric layer on a high voltage I/O transistor includes steps of conducting thermal oxidation or deposition of SiON dielectric layer on top of the substrate, and etching away the SiON dielectric layer on the low voltage core transistor side.

12. The manufacturing method for an analog integrated circuit with improved transistor lifetime of claim 11, wherein the step of etching away the SiON dielectric layer on the low voltage core transistor side includes the step of conducting a dry etching technique to etch away the SiO₂ dielectric layer on the high voltage I/O transistor side.

13. The manufacturing method for an analog integrated circuit with improved transistor lifetime of claim 7, wherein the step of depositing and patterning a SiO₂ dielectric layer on a low voltage core transistor includes steps of conducting thermal oxidation or deposition of SiO₂ dielectric layer on top of the substrate, and etching away the SiO₂ dielectric layer on the high voltage I/O transistor side.

14. The manufacturing method for an analog integrated circuit with improved transistor lifetime of claim 13, wherein the step of etching away the SiO₂ dielectric layer on the high voltage I/O transistor side includes a step of conducting a dry etching technique to etch away the SiO₂ dielectric layer on the high voltage I/O transistor side.

15. The manufacturing method for an analog integrated circuit with improved transistor lifetime of claim 7, wherein the step of forming a source electrode, a gate electrode and a drain electrode for the low voltage core transistor includes the step of filling metal into the open holes of the SiON passivation layer on top of the source, the gate and the drain regions of the low voltage core transistor.

16. The manufacturing method for an analog integrated circuit with improved transistor lifetime of claim 7, wherein the step of forming a source electrode, a gate electrode and a drain electrode for the high voltage I/O transistor includes the step of filling metal into the open holes of the SiON passivation layer on top of the source, the gate and the drain regions of the high voltage I/O transistor.
